(19) United States
(12) Patent Application Publication
(10) Pub. No.: US 2026/0052650 A1
(43) Pub. Date: Feb. 19, 2026

(54) Cryogenic Cooling System

(71) Applicant: Donald Wade Barker, Gallatin, TN (US)

(72) Inventor: Donald Wade Barker, Gallatin, TN (US)

(21) Appl. No.: 19/273,108

(22) Filed: Jul. 17, 2025

Related U.S. Application Data
(60) Provisional application No. 63/673,060, filed on Jul. 18, 2024.

(51) Int. Cl. H05K 7/20

(52) U.S. Cl. CPC H05K 7/20372; H05K 7/20327; H05K 7/208

(57) ABSTRACT

A cooling system has at least one cryogenic cell, a plurality of air-coolant heat exchangers, and a cooling circuit. The cooling circuit is connected between each of the plurality of air-coolant heat exchangers and the at least one cryogenic cell and conveys a circulating coolant between the plurality of air-coolant heat exchangers and the at least one cryogenic cell without a change in phase of the circulating coolant. Each of the plurality of heat exchangers may be associated with a fan. In some cases, the cooling system may include a coolant mixing subsystem that mixes warm coolant with coolant chilled by the at least one cryogenic cell to create the circulating coolant. The coolant mixing subsystem may include a manifold that supplies the circulating coolant to each of the plurality of air-coolant heat exchangers. Methods of controlling such systems include adjusting the temperature of the coolant for each heat exchanger.

### CROSS-REFERENCE TO RELATED APPLICATIONS

This application claims priority to, and the benefit of, U.S. Provisional Patent Application No. 63/673,060, filed Jul. 18, 2024, the contents of which are incorporated by reference in their entirety.

### TECHNICAL FIELD

The invention relates to a cryogenic cooling system.

### BACKGROUND

Since their advent, air conditioning systems have largely used compression-expansion refrigeration cycles with chemical refrigerants like ammonia and haloalkanes. A cold mixture of liquid and vapor-phase refrigerant passes through an evaporator (i.e., a heat exchanger), where it absorbs heat from air, vaporizes, and is then compressed back into liquid form by a compressor.

U.S. Pat. No. 11,306,957 discloses an alternative: a cryo-refrigeration system. In this system, a cryogenic cell includes an inner vessel filled with liquid nitrogen. Coils are wrapped around the inner vessel, and an outer vessel encapsulates the coils. A circulating coolant fluid, typically propylene glycol, runs through the coils. As the coolant fluid circulates around the inner vessel, it exchanges heat with the liquid nitrogen within. As the liquid nitrogen vaporizes, it is regenerated using a cold head filled with a colder cryogen.

While the system of this patent has great potential—including the potential to cool to lower temperatures with less toxic materials at lower cost—there are issues. One of those issues is overshoot: the liquid nitrogen used to cool the circulating coolant is so cold that the circulating fluid may produce unacceptable temperature differentials.

### BRIEF SUMMARY

Aspects of the invention relate to cooling systems, for example, systems used to provide comfort cooling or cooling of electronic equipment in a space. A cooling system may comprise a plurality of air-coolant heat exchangers, at least one cryogenic cell, and a cooling circuit connected between each of the plurality of air-coolant heat exchangers and the at least one cryogenic cell. The cooling circuit conveys a circulating coolant between the plurality of air-coolant heat exchangers and the at least one cryogenic cell without a change in phase of the circulating coolant. Each of the plurality of air-coolant heat exchangers may be associated with a fan.

The cooling system may include a coolant mixing subsystem. The coolant mixing subsystem may include a first coolant reservoir, a second coolant reservoir, and a mixing apparatus. The first coolant reservoir is adapted to hold and to direct a first coolant through the at least one cryogenic cell to cool the first coolant to a first temperature. The second coolant reservoir is associated with one or more heaters and is adapted to hold and to heat a second coolant to a second temperature. The second temperature is higher than the first temperature, and the first coolant and the second coolant are the same except as to temperature. The mixing apparatus is constructed and arranged to mix the first coolant and the second coolant to create the circulating coolant. The mixing apparatus may be, for example, a mixing valve or a manifold. If the mixing valve is a manifold, it may mix the circulating coolant to a different temperature for each of the plurality of heat exchangers.

In these cooling systems, a cryogenic cell is a device adapted to cool fluids. The cryogenic cell comprises a core adapted to contain a cryogen. The core has one or more ports to an outside of the cryogenic cell that allow the cryogen to circulate into and out of the core. A mid-wall is disposed around the core in such a way that it is spaced from the core. The mid-wall defines, in part, a space in selective, partial thermal communication with the core. The space is at least substantially airtight and is adapted to be filled or evacuated with a compressible fluid that (1) increases or decreases thermal communication with the core in accordance with a pressure of the compressible fluid within the space, and (2) places contents of the space under the pressure of the compressible fluid. A conduit is positioned within the space such that the conduit does not make physical contact with the core. The conduit is connected with inlet and outlet ports in the cryogenic cell. The cryogenic cell does not include a cold head within the core; instead, the core may be directly connected to a cryogenic regenerator to regenerate the cryogen into liquid form.

In these cooling systems, an individual heat exchanger and associated fan may be installed in each of a number of rooms or separate spaces. Because a manifold may mix the circulating coolant to a different temperature for each of the individual heat exchangers, systems may be able to serve the individual cooling needs of each space. In some cases, these cooling systems may decouple cooling functions from air circulation functions.

Another aspect of the invention relates to methods for controlling a cooling system like that described above. In these methods, the temperature of a space served by the cooling system is measured. If the measured temperature is not the desired temperature, the temperature of the circulating coolant supplied to the heat exchanger is changed. This may be done by mixing warm and cold coolant to a different temperature for that particular heat exchanger.

Other aspects, features, and advantages of the invention will be set forth in the following description.

### BRIEF DESCRIPTION OF THE DRAWING FIGURES

The invention will be described with respect to the following drawing figures, in which like numerals represent like features throughout the description, and in which:

FIG. 1 is a perspective view of a cryogenic cell according to one embodiment of the invention;

FIG. 2 is a cross-sectional perspective view taken through Line 2-2 of FIG. 1;

FIG. 3 is an enlarged cross-sectional perspective view of a portion of FIG. 2;

FIG. 4 is a cross-sectional view of the cryogenic cell taken through Line 2-2 of FIG. 1, shown with a cryogenic regenerator and illustrating the manner in which cold cryogen within the core of the cryogenic cell is regenerated;

FIG. 5 is a schematic illustration of the use of two cryogenic regenerators in parallel to serve a single cryogenic cell;

FIG. 6 is a schematic illustration of the use of two cryogenic regenerators in series to serve a single cryogenic cell;

FIG. 7 is a schematic illustration of the use of bypasses in the configuration of FIG. 6 in order to allow only one of the two cryogenic regenerators to function at a time;

FIG. 8 is a schematic illustration of one of the ports connected to the core, illustrating the use of multiple connections to that port, and particularly showing a pressure relief valve connected to the port;

FIG. 9 is a schematic illustration similar to the view of FIG. 8, illustrating the connection of a pneumatic valve to the port;

FIG. 10 is a schematic illustration of the use of one cryogenic regenerator connected to two cryogenic cells;

FIG. 11 is a schematic illustration of a system in which a plurality of cryogenic cells are connected to a plurality of regenerators by way of a manifold; and

FIG. 12 is a schematic flow diagram of a method for controlling the system of FIG. 11;

FIGS. 13-14 are cross-sectional views of cryogenic cells according to other embodiments, with different core and cell proportions and volumes;

FIG. 15 is a schematic illustration of a cryogenic air-cooling system that uses the cryogenic cell of FIG. 1 in a closed-loop configuration with an air-coolant heat exchanger;

FIG. 16 is a schematic illustration of another cryogenic air-cooling system that mixes warm coolant with cold coolant to provide individualized cooling to a plurality of heat exchangers;

FIG. 17 is an illustration of an application of the system of FIG. 16, showing the system of FIG. 16 cooling a number of individual enclosures;

FIG. 18 is a schematic flow diagram of a method for controlling the system of FIG. 17;

FIG. 19 is a perspective view of an office space, illustrating a system according to an embodiment of the invention installed as a chilled beam; and

FIG. 20 is a cross-sectional view of the chilled beam of FIG. 19.

### DETAILED DESCRIPTION

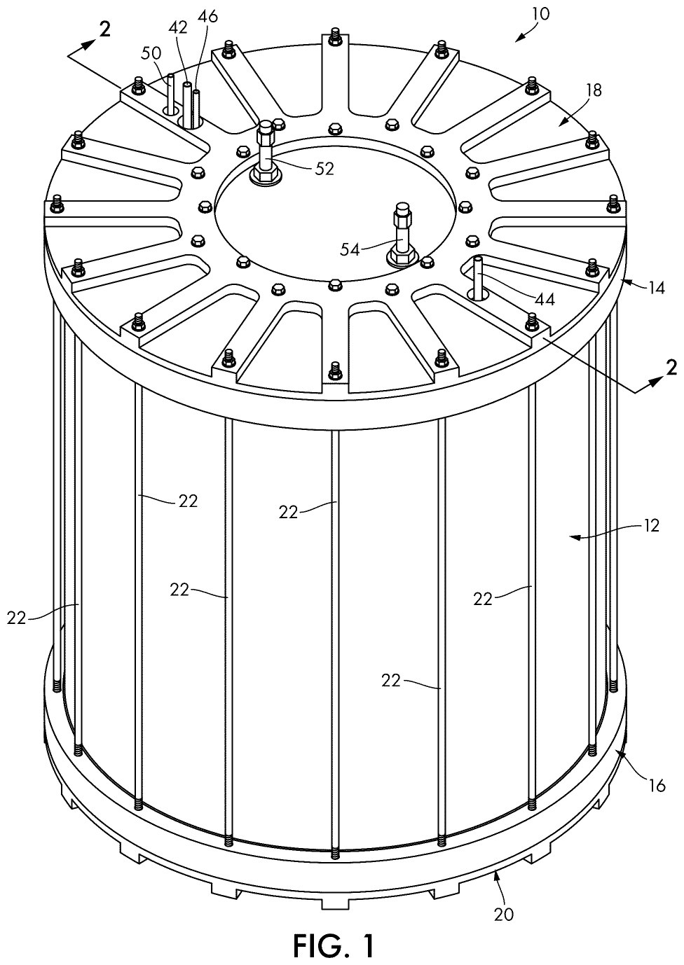

FIG. 1 is a perspective view of a cryogenic cell, generally indicated at 10, according to an embodiment of this description. The cryogenic cell 10 of FIG. 1 is generally cylindrical in overall shape, with a cylindrical sidewall 12, a top 14, and a bottom 16. The top 14 and the bottom 16 are reinforced with reinforcing plates 18, 20, which will be discussed in greater detail below. As can be seen in FIG. 1, the cryogenic cell 10 is reinforced and held together along its longitudinal axis by a number of tie rods 22, which extend from, and are received in, the top 14 to the bottom 16, and are bolted in place.

As used here, the term “longitudinal axis” refers to an axis aligned with the centers of the top 14 and the bottom 16 and extending between the top 14 and the bottom 16. The term “longitudinal direction” refers to a direction parallel to or along the longitudinal axis. The terms “radial direction” and “radially” refer to a direction that extends between the longitudinal axis and the sidewall 12.

In the cryogenic cell 10, the exterior sidewall 12, top 14, and bottom 16 primarily offer thermal insulation. To that end, it is helpful if the materials of which these components 12, 14, 16 are made have thermal insulating properties, can withstand cryogenic temperatures without shattering, and are machinable, moldable, castable, or otherwise workable. Ultra-high molecular weight (UHMW) polyethylene is one such material and, e.g., the top 14 and the bottom 16 may be made of UHMW polyethylene. However, the cryogenic cell 10 and its components 12, 14, 16 need not be made, or made entirely, of expensive or exotic materials. For example, the sidewall 12 may be made of high-density polyethylene (HDPE), e.g., HDPE pipe. A wall thickness of about 2-3 inches (5-7.6 cm) may be appropriate in at least some embodiments. In one embodiment, the sidewall 12 may be an HDPE pipe with an outer diameter of 34 inches (86.4 cm) and an inner diameter of 31 inches (78.7 cm).

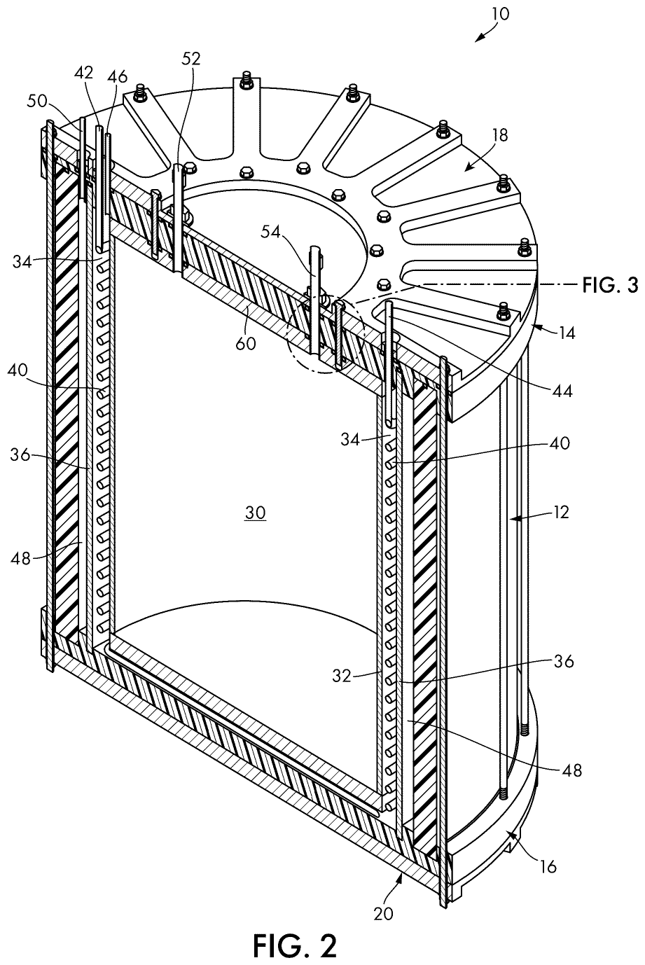

FIG. 2 is a cross-sectional view of the cryogenic cell 10, taken through Line 2-2 of FIG. 1. The cryogenic cell 10 has a core 30, which is centered about the longitudinal axis. The core 30 is a vessel with at least a sidewall 32 that is made of a thermally-conductive material. In the illustrated embodiment, the entire core 30 is made of 6061 T6 aluminum, although other materials, like copper, may be used depending on the pressures at which the cryogenic cell 10 is to operate.

A pressurizable space 34 is defined between the sidewall 32 of the core 30 and a mid-wall 36 that is positioned radially outward of the sidewall 32 of the core 30. The mid-wall 36 extends between the top 14 and the bottom 16, fully separating the pressurizable space 34 from other compartments and portions of the cryogenic cell 10. The sidewall 12 is positioned radially outward of the mid-wall 36, with a gap between the mid-wall 36 and the sidewall 12.

A set of tubing 40 runs within the pressurizable space 34, generally coiled around the core 30. However, the set of tubing 40 is not in direct physical contact with the sidewall 32 or any other portion of the core 30. If spacers or other such structures are needed to maintain the position of the tubing 40, those spacers would generally not be thermally conductive. The set of tubing 40 is continuous between an inlet port 42 and an outlet port 44, both of which connect to the set of tubing 40 and penetrate the top 14. A length of the tubing 40 passes under the core 30 and is shown longitudinally sectioned in FIG. 2. The set of tubing 40 is but one example of the kind of conduit that may be present in the pressurizable space 34. In some embodiments, conduit may be used that does not coil around the core 30, is not round, or is otherwise adapted for a particular application.

At least one additional port 46 is used to charge the pressurizable space 34 and, when necessary, to remove pressure. For example, air or nitrogen gas may be pumped into the pressurizable space 34 to create a pressure. Additionally, the space 48 between the mid-wall 36 and the outer sidewall 12 may include a port 50 that, among other things, allows the space 48 to be evacuated for better thermal insulation, if needed.

The core 30 also includes a number of ports. More specifically, the core includes cryogen inlet and outlet ports 52, 54. The purpose of these ports will be explained in more detail below. Although there are only two ports 52, 54 that penetrate into the core 30, various connectors may be used to provide for additional connections, or to provide additional functionality.

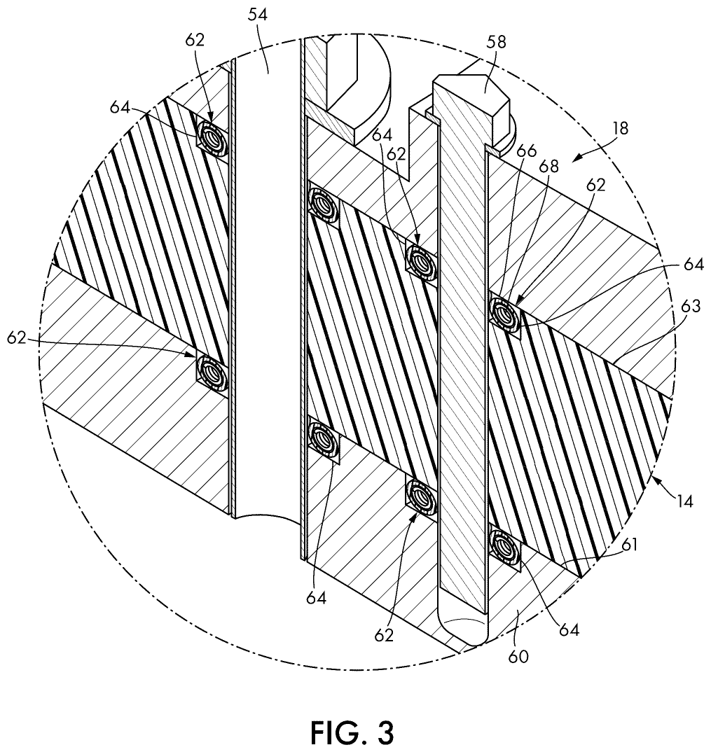

FIG. 3 is an enlarged view of a portion of FIG. 2, showing a bolt 58 and one of the ports 54 in the core 30. The bolt 58 inserts through the plate 18 and the top 16, terminating in the lid 60 of the core 30. The port 54 inserts through all three layers 18, 16, 60 and opens into the core 30 itself. To prevent leaks around the penetrations, circular O-ring grooves 64 are cut in the upper face 61 of the lid 60 of the core 30 and in the upper face 63 of the top 14 around the positions of each penetration. O-rings 62 are installed in those grooves 64.

In some applications, the O-rings 62 might be made of a conventional elastomer. However, it has been found that when conventional elastomeric O-rings are exposed to cryogenic temperatures, they lose all elasticity and shatter. Therefore, the O-rings 62 of the illustrated embodiment are made of a composite of materials. More specifically, an outer tube of polymeric material 66 is backed by an inner coil 68 of metal wire, such as a helix or double helix of 316 stainless steel wire. The outer tube of polymeric material 66 may be, e.g., perfluoroalkoxy (PFA) plastic.

As those of skill in the art will appreciate, heat transfer occurs by conduction, convection, and radiation. By adding gas to the pressurizable space 34 through the port 46, one increases the amount of mass in the space 34, and thus, the level of heat transfer that can occur by conduction and convection. By withdrawing gas from the pressurizable space 34 (or drawing a vacuum on the pressurizable space 34), one reduces the amount of mass in the space 34, and thus, the ability of heat to flow between the core 30 and the pressurizable space 34 by conduction and convection.

Thus, the pressurizable space 34 can be placed under essentially any conditions of temperature and pressure: as pressure is increased within the pressurizable space 34, conduction and convection increase, and thus, the rate of heat exchange with the core 30 also increases, making the pressurizable space 34 both colder and higher-pressure. When pressure within the pressurizable space 34 is lessened, the rate of heat transfer with the core 30 decreases. This has a number of potential uses, some of which will be described below.

As the core 30 experiences heat transfer with the pressurizable space 34, the cryogen within the core 30 will heat up and begin to vaporize. As that occurs, the ability of the core 30 to absorb heat will gradually decline. In the cryogenic cell of U.S. Pat. No. 11,448,459, the cryogen within the core is regenerated into cold, liquid phase by a cold head filled with a colder cryogen (e.g., liquid helium if liquid nitrogen is the primary cryogen within the core).

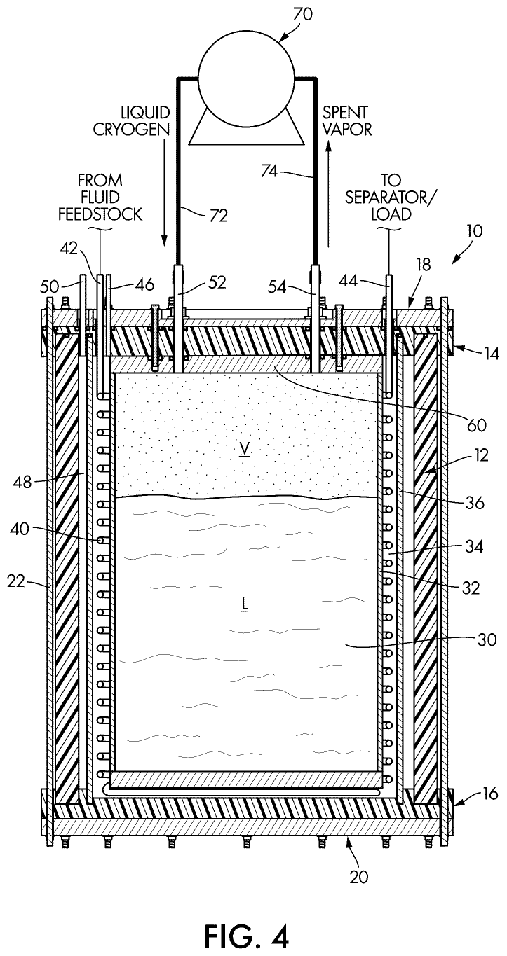

By contrast, the cryogenic cell 10 of the present embodiment, there is no cold head in the core 30, as can be seen in FIG. 4. FIG. 4 is a cross-sectional view of the cryogenic cell 10, again taken through Line 2-2 of FIG. 1. In the view of FIG. 4, two of the ports 52, 54 that connect to the core 30 are connected to a cryogenic regenerator 70. The cryogenic regenerator 70 is adapted to regenerate gaseous cryogen into liquid form and may be, e.g., a Stirling engine or another such device. The cryogenic regenerator 70 may also be an external Gifford-McMahon cold head and associated compressor. The cryogenic regenerator 70 may be under pressure. For example, if the cryogenic regenerator 70 is a Gifford-McMahon cold head, the cold head may be placed within a manifold that is kept under pressure.

In operation, the cryogenic regenerator 70 forms a closed circuit with the core 30 of the cryogenic cell 10. In that circuit, one of the ports 52 serves as an inlet port, through which the cryogenic regenerator 70 deposits liquid cryogen. The other port 54 serves as an outlet port, through which the cryogenic regenerator 70 removes vaporized cryogen. If necessary, the ports 52, 54 may terminate in tubes that extend down to appropriate vertical positions within the core 30.

During operation, because of heat transfer with the core 30, there will typically be both liquid-phase cryogen, labeled L in FIG. 4, and vapor-phase cryogen, labeled V in FIG. 4, in the core 30 at any one time. The rate of heat transfer with the core 30 will determine the rate at which the liquid cryogen L vaporizes. The capacity of the cryogenic cell 10 to cool the pressurizable space 34 (i.e., the heat transfer rate with the core 30 per unit time) will depend on the rate at which the cryogenic regenerator 70 can remove cryogenic vapor V, compress it back into liquid cryogen L, and return the liquid cryogen L to the core 30.

This arrangement—connecting the core 30 to an external cryogenic regenerator 70—removes the cold head found in prior cryogenic cell designs but retains its function; i.e., the cryogenic cell 10 can still regenerate the cryogen in its core 30. A cryogenic cell 10 without a cold head also has certain other advantages. For example, removing the cold head from the cryogenic cell 10 may, in many cases, have the effect of removing all moving parts from the cryogenic cell 10. This, in turn, may improve reliability and reduce the risk that fluids flowing through the set of tubing 40, which may be flammable, will come into contact with a spark.

Although the cryogenic regenerator 70 is illustrated as being relatively close to the cryogenic cell 10 in the view of FIG. 4, the cryogenic regenerator 70 may be remote from the cryogenic cell 10, e.g., in the next room. So long as the supply 72 and return 74 lines can be kept properly insulated or otherwise arranged to minimize heat transfer with the surrounding environment, the cryogenic regenerator 70 may be placed at any distance relative to the cryogenic cell 10.

The cryogen inlet and outlet ports 52, 54 are shown in the embodiment of FIGS. 1-4 as being separate physical structures that enter the cryogenic cell 10 and the core 30 at separate points. This may be the case in many embodiments. In other embodiments, inlet and outlet ports may enter the cryogenic cell 10 as part of a single, combined structure that penetrates the cryogenic cell 10 at a single location. From that single structure, separate inlet and outlet conduits may branch away from one another within the core 30.

As those of skill in the art will appreciate, in some applications, the cryogenic regenerator 70 is an optional component. That is, there may be applications in which the amount of mass to be processed by the cryogenic cell 10 is small enough and the volume of the core 30 is large enough that it is not necessary to regenerate the cryogen vapor V that forms within the core 30 into liquid form. In that case, one would simply fill the core 30 and seal the port or ports 52, 54—and it may not be necessary to have or to use both ports 52, 54.

However, for perhaps the vast majority of applications, particularly those involving continuous flow through the pressurizable space 34, some form of regeneration using a cryogenic regenerator 70 will be used. Depending on the heat transfer requirements of the application, the cryogenic regenerator 70 may be used either intermittently or continuously.

As shown in FIG. 4, a single cryogenic cell 10 connected to a single cryogenic regenerator 70 form a system. In that system, the cryogenic regenerator 70 is a single point of failure; that is, if the cryogenic regenerator 70 fails, the system as a whole fails. To prevent that from happening, it is possible to connect more than one cryogenic regenerator 70 to a single cryogenic cell 10.

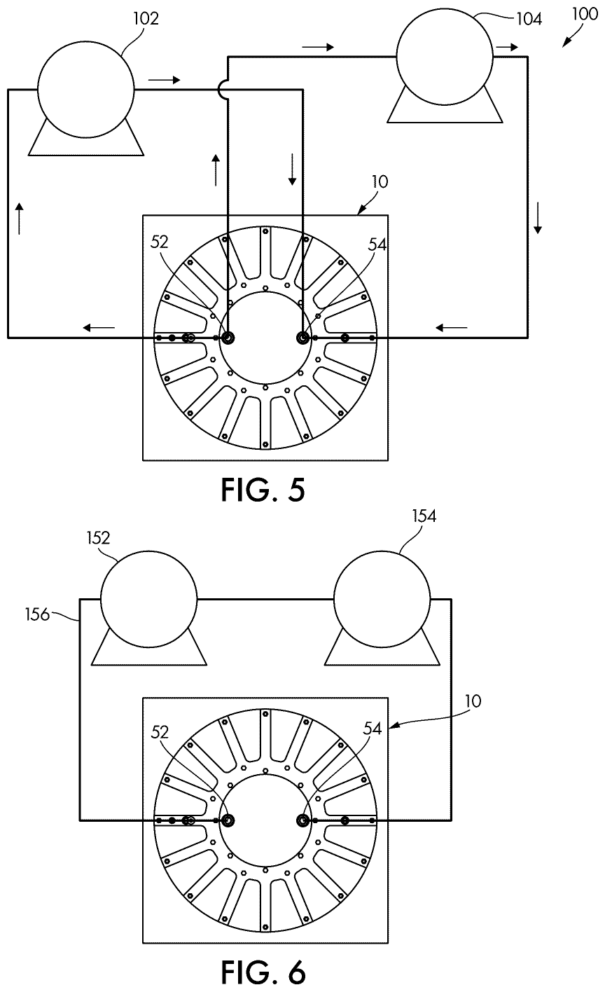

FIG. 5 is a schematic illustration of a system, generally indicated at 100, in which two regenerators 102, 104 are connected to the same cryogenic cell 10. Each cryogenic regenerator 102, 104 is connected to the input and output ports 52, 54 of the cryogenic cell 10. In general, any number of cryogenic regenerators 70, 102, 104 may be connected to a cryogenic cell 10, and those cryogenic regenerators 70, 102, 104 may be arranged either in serial or in parallel. The arrangement of FIG. 5 is with the two cryogenic regenerators 102, 104 in parallel. With two cryogenic regenerators 102, 104 in parallel, should one cryogenic regenerator 102, 104 fail, the other cryogenic regenerator 102, 104 can be brought online to perform its function. However, the cryogenic regenerators 102, 104 need not be operated one-at-a-time. In some situations, it may be advantageous to use two or more cryogenic regenerators 102, 104 in parallel, as doing so may increase the volume of cryogen vapor V that can be compressed back into liquid form per unit of time. Variations on this are also possible: e.g., one cryogenic regenerator 102, 104 can be engaged when the other cryogenic regenerator 102, 104 reaches its functional limits, or the load can be balanced between the two cryogenic regenerators 102, 104. If two cryogenic regenerators 102, 104 are arranged in parallel and used simultaneously, they may be the same, i.e., have the same functional characteristics and specifications, or they may be different.

FIG. 6 is a schematic illustration of a system 150 in which two cryogenic regenerators 152, 154 are used in series. If the two cryogenic regenerators 152, 154 are the same, one cryogenic regenerator 152, 154 may be activated to take over for a failed cryogenic regenerator 152, 154. In that case, bypasses may be installed so that an inoperative cryogenic regenerator 152, 154 can be bypassed.

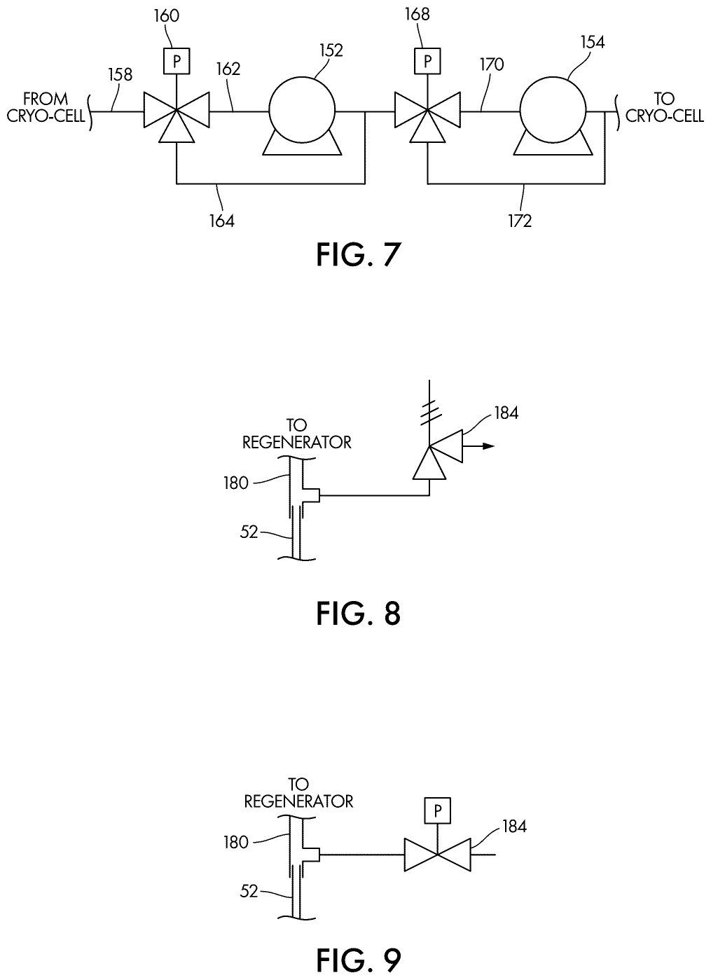

FIG. 7 is an illustration of a variation on system 150 in which such bypasses are installed. More specifically, in FIG. 7, fluid flows through a first conduit 158 and encounters a first three-way valve 160. The first three-way valve 160 either allows the fluid to continue to flow through a conduit 162 toward the first cryogenic regenerator 152 or diverts the fluid flow through a first bypass loop 164 which avoids the first cryogenic regenerator 152 and directs the fluid flow through a conduit 166 toward the second cryogenic regenerator 154. Fluid in the conduit 166 encounters a second three-way valve 168 which either allows the fluid flow to continue through a conduit 170 toward the second cryogenic regenerator 154 or diverts the flow through a second bypass loop 172 which avoids the second cryogenic regenerator 154.

If the two cryogenic regenerators 152, 154 are not identical, various possibilities arise. For example, two cryogenic regenerators 152, 154 used in series could allow for a multi-stage compression process, where a first cryogenic regenerator 152 compresses the incoming cryogen vapor V to particular conditions, and the second cryogenic regenerator 154 completes the compression into liquid form.

As was described above, although the cryogenic cells 10 described above have only two ports 52, 54 that penetrate into the core 30, those ports 52, 54 may be connected to various connectors to provide for additional connections and, in some cases, additional functionality. For example, in the schematic view of FIG. 8, one of the ports 52 is coupled to a T-connector 182, which is, in turn, connected to a pressure relief valve 182. If the cryogenic regenerator 70 fails, there is no backup cryogenic regenerator, and liquid cryogen L within the core 30 continues to vaporize, as the pressure within the core 30 mounts, there is the chance of failure of the vessel; that is, the cryogenic cell 10 could ultimately burst. The pressure relief valve 182 prevents this: if the pressure within the core 30 exceeds the limit of the pressure relief valve 182, the pressure relief valve 182 opens, releasing the excess pressure.

FIG. 9 shows an alternate configuration of this, in which the port 52 is connected to a T-connector 180, one outlet of which is connected to a pneumatically-actuated valve 184. Such a valve 184 would allow the cryogenic regenerator 70 to be bypassed and the contents of the core 30 to be either diverted or vented to atmosphere.

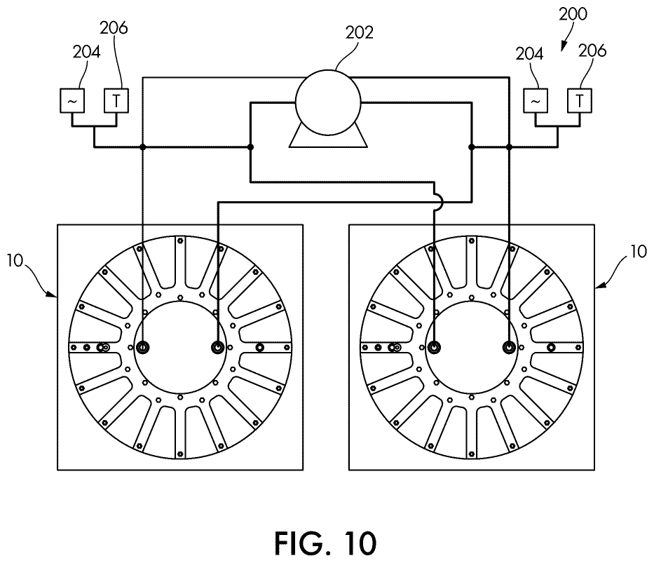

Although the above focuses on multiple cryogenic regenerators being connected to a single cryogenic cell 10, the converse is also possible, i.e., one cryogenic regenerator may be connected to more than one cryogenic cell 10. FIG. 10 is an illustration of a system, generally indicated at 200, in which two cryogenic cells 10 are connected to a single cryogenic regenerator 202. In this system 200, depending on the particular arrangement, cryogen vapor V that is withdrawn from one cryogenic cell 10 may or may not be returned to the same cryogenic cell 10 as liquid cryogen L. In order to monitor the flow into and out of the cryogenic cells 10 and ensure that the core 30 of each cryogenic cell 10 is properly filled, system 200 has flow meters 204 in or coupled to the input and output lines. Temperature sensors 206, such as thermocouples, may also be included.

In system 200, the cryogenic regenerator 202 may serve both cryogenic cells 10 simultaneously, or the cryogenic regenerator 202 may serve the cryogenic cells 10 one at a time, switching back and forth between the cryogenic cells 10 to serve them. Various valves and fittings, which for the sake of simplicity are not shown in FIG. 10, may be used to isolate one cryogenic cell 10 or the other.

Systems like system 200 may not provide the redundancy of systems in which there are multiple cryogenic regenerators 70, 102, 104, 152, 154, but where cost is a particular consideration, reliability is less of a concern, and the rate of heat exchange with the core 30 is not extreme, a system like system 200 may be ideal.

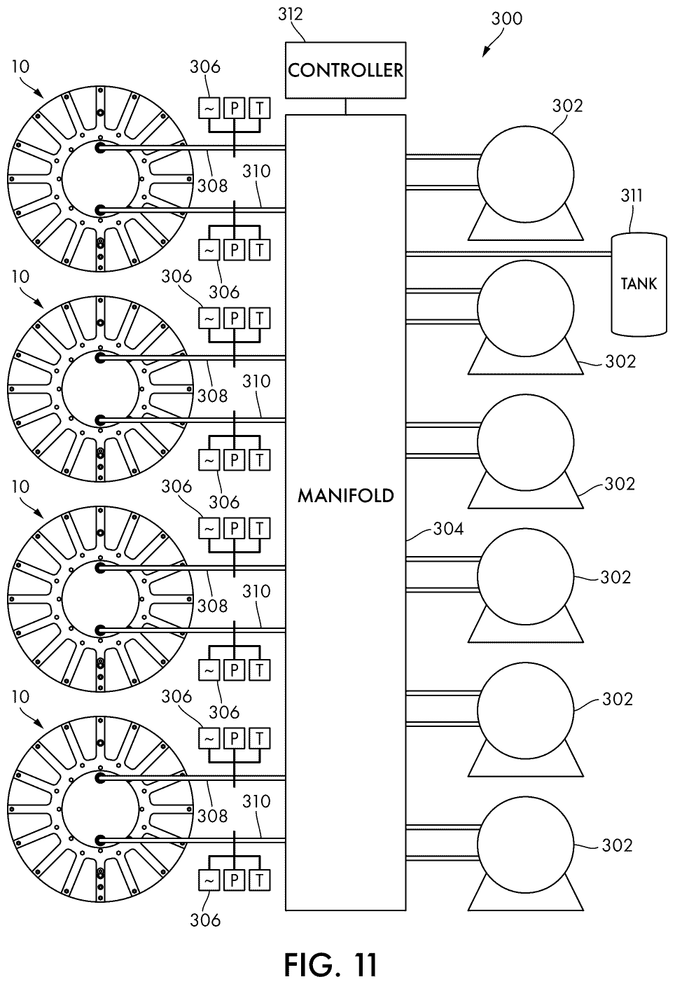

In all of the description above, it is assumed that the connections between the cryogenic cell 10 and any cryogenic regenerators 70, 102, 104, 152, 154 that are connected to it are individual connections made with various connectors. That may not always be the case. FIG. 11 is a schematic diagram of a system, generally indicated at 300, in which there are six cryogenic regenerators 302 serving four cryogenic cells 10 through a manifold 304. A separate manifold 304 would typically be provided for each cryogen that is used in the system 300. If, for example, system 300 is organized into multiple stages, each of which uses a different cryogen in the cores 30 of its cryogenic cells 10, then a manifold 304 may be provided for each stage. On the other hand, if multiple stages use the same cryogen, then the same manifold 304 may serve those multiple stages. For that reason, this description assumes that all of the cryogenic cells 10 in FIG. 11 use the same cryogen.

Although the cryogenic regenerators 302 are schematically shown as being outside the manifold 304, in some embodiments, at least a portion of the cryogenic regenerators 302 may be disposed within the manifold 304. For example, cold heads may be placed within the manifold, with supporting cryogenic compressors outside the manifold 304. Particularly if cold heads or other regenerating structures lie within the manifold 304, the manifold 304 may be maintained at high pressure, such that both the material to be regenerated and the cold heads are held under pressure. That pressure may be at, near, or greater than the pressure of the cores in some embodiments.

As in system 200, with the manifold 304 of system 300, cryogenic vapor V removed from one cryogenic cell 10 will not always be redeposited as liquid cryogen L in the same cryogenic cell 10. Therefore, a sensor or sensor suite 306 monitors the inflow and outflow lines 308, 310 into and out of the cryogenic cells 10. The contents and particular sensors in the sensor suite 306 may vary from embodiment to embodiment, depending on how system 300 is controlled. Typically, the sensor suite 306 would include a flow sensor, to monitor the flow into and out of the core 30, and optionally, a temperature sensor. Additionally, the sensor suite 306 may be equipped with a pressure sensor in each of the lines 308, 310, or at least in the outflow line 310 of each cryogenic cell 10. Although FIG. 11 shows multiple sensor suites 306, one in each line 308, 310, in some cases, a single instrument that can receive and process multiple flows simultaneously may be used. The lines 308, 310 may be diverted through such an instrument, instead of extending directly between the cryogenic cells 10 and the manifold 304.

In some embodiments, a system like system 300 may optionally include, or be coupled to, a surge tank 311, which contains additional cryogen that can be introduced into system 300 in case of high demand, leaks, and other situations in which additional cryogen would be useful. In the illustrated embodiment, the surge tank 311 is connected to the manifold 304, but not directly to any of the cryogenic cells 10. A valve or valves (for simplicity, not shown in FIG. 11) may be placed to control flow into and out of the surge tank 311.

A controller 312, which may be a microprocessor, a microcontroller, an application-specific integrated circuit (ASIC), an integrated, embedded system including one of those components, or a programmable logic controller (PLC), controls the manifold 304 to control the flows of cryogen into and out of the cores 30 of the cryogenic cells 10. Several general principles may guide the manner in which the controller 312 controls the manifold 304. For example, as may be apparent from the description above, ideally, the pressure of cryogen vapor V within the core is as low as possible. That is, ideally, as soon as cryogen vapor V is formed by heat exchange with the pressurizable space 34, that cryogen vapor V is removed and replaced by liquid cryogen L. If cryogen vapor V is forming rapidly within the core 30, it means that the cryogenic cell 10 is experiencing a heavy thermal load. As the amount of cryogen vapor V increases, the pressure within the core 30 increases, and the controller 312 should act to relieve that pressure. However, as cryogen flows into and out of the core 30 of each cryogenic cell 10, the controller 312 should maintain at least some threshold volume of liquid cryogen L in the core. That is, the cryogenic regenerators 302 and manifold 304 should maintain a dynamic equilibrium that keeps at least a threshold amount of liquid cryogen L in the core 30 of each cryogenic cell 10, as a core 30 that is completely drained will be unable to absorb any heat from the pressurizable space 34.

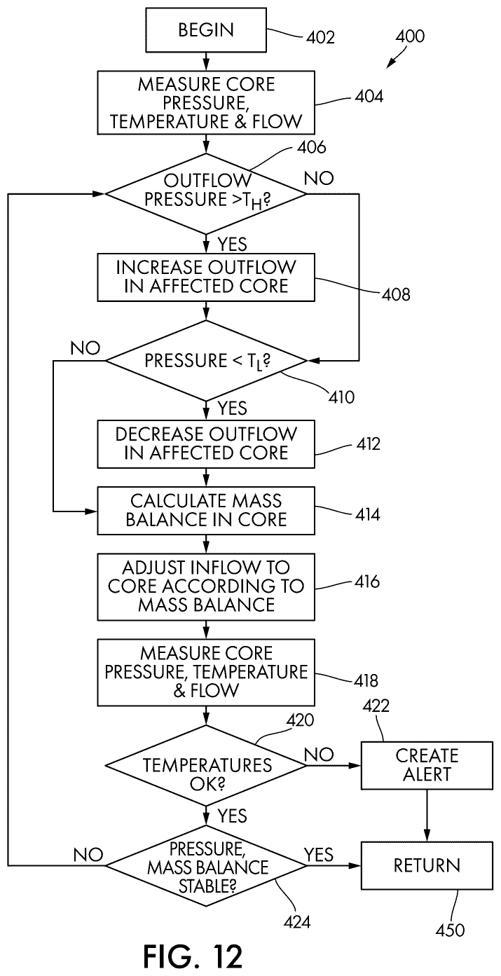

FIG. 12 is a schematic flow diagram of a method, generally indicated at 400, for controlling a manifold-based system like system 300. Method 400 operates according to the general principles outlined above and begins at 402. For simplicity in explanation, method 400 will be set forth with reference to a single cryogenic cell 10 and its core 30. In task 404, the controller 312 measures the temperatures in the inflow and outflow lines 308, 310 of the core 30, as well as the pressures in the lines 308, 310, and the flow rates in the lines 308, 310. Additionally, prior to task 402, the controller 312 would typically be programmed with the initial volume or mass of cryogen in the cryogenic cell 10, as well as other operating parameters. Method 400 continues with task 406.

Task 406 is a decision task. In task 406, if the measured pressure in the outflow line 308 is higher than a predefined threshold TH (task 406: YES), that is an indication that heat transfer within the core 30 is high. Thus, method 400 continues with task 408. If the measured pressure in the outflow line 308 is not higher than the defined threshold (task 406: NO), method 400 continues with task 410.

In task 408, the controller 408 increases the outflow in the affected core 30, drawing more of the cryogen vapor V out of the core 30 to reduce the pressure in the core. Method 400 continues with task 410.

In task 410, the controller 312 checks whether the pressure in the core 30 is less than a defined threshold (TL). While it may be ideal to reduce the pressure in the core 30 to zero, such that there is only liquid cryogen L within the core 30, that may be a practical impossibility. Thus, the controller 312 is programmed with the defined low threshold TL. If the pressure in the core 30 reaches that threshold (task 410: YES), the controller 312 may slow the outflow rate in task 412 to divert necessary resources to other cryogenic cells 10. As those of skill in the art will note, if the cryogen in the core 30 will not remain in liquid phase at ambient pressure, the defined low threshold TL may be set higher, so that enough pressure is maintained in the core 30 to keep the cryogen in liquid phase.

Method 400 continues with task 414, and the controller 312 calculates the mass balance in the core 30 based on the detected flows. Tasks 406-412 of method 400 concern the rate at which cryogenic vapor V is removed from the core 30. In order to maintain mass balance within the core 30, liquid cryogen L must be added. Thus, based on the calculations in task 414, the controller 312 adjusts the inflow to the core 30 in task 416 to maintain mass balance, i.e., the appropriate volume of liquid cryogen L in the core 30. Method 400 continues with task 418.

In task 418, the controller 312 again measures the pressure and temperature of the core 30 and the flow in the lines 308, 310. Method 400 continues with task 420, a decision task. In task 420, if the temperatures are within predefined limits (task 420: YES), method 400 continues with task 424. If the temperatures are not within the predefined limits (task 420: NO), method 400 continues with task 422 and an alert is established at task 422 before method 400 returns at task 450.

Task 424 is another decision task. In task 424, if the pressure in the core 30 is stable and the calculated mass balance is also stable (task 424: YES), method 400 returns at 450. If any of these things are not stable (task 424: NO), method 400 returns to task 406.

Method 400 presents a relatively simple algorithm for a single cryogenic cell 10: if the pressure of the cryogenic vapor V is too high, increase outflow from the core 30 and adjust the inflow to maintain mass balance. If the pressure of the cryogenic vapor V reaches a low-threshold, reduce the outflow in order to reallocate resources and adjust the inflow to maintain mass balance. In a practical implementation, however, the controller 312 may have many more factors to consider. For example, after determining in task 406 that the pressure in a core 30 is too high, the controller 312 may examine whether there is sufficient capacity to increase the outflow to that core 30. In making that decision, the controller 312 may examine whether all cryogenic regenerators 302 are online, the relative loads on each cryogenic regenerator 312, and whether a sufficient volume of liquid cryogen L is available. This latter issue may be addressed by releasing additional liquid cryogen L from the surge tank 311. If the cryogenic cells 10 have pressure-relief valves 182 installed, the controller 312 may be programmed to maintain a lower pressure in the core 30 than the pressure at which the pressure-relief valves 182 actuate.

In many embodiments, multiple cryogenic cells 10 will receive equal amounts of fluid to process in parallel. In those embodiments, there is usually no need to prioritize one cryogenic cell 10 over another. However, even in those situations, the kind of resource allocation and shifting can be used to address a cryogenic cell 10 that is malfunctioning or underperforming (e.g., after task 422 of method 400 and before method 400 returns at task 450). In an extreme case, the controller 312 may simply close valves that lead to a particular cryogenic cell 10, essentially turning it off.

There may also be embodiments in which cryogenic cells 10 receive fluid in series. This may be the case, for example, if it is necessary to pre-cool an incoming fluid to a particular initial temperature in one cryogenic cell 10 before taking that fluid to a second, lower temperature in another cryogenic cell 10. If the cryogenic cells 10 are arranged in a series configuration (or some kind of mixed series-parallel configuration), then it may be desirable to prioritize the needs of certain cryogenic cells 10 or sets of cryogenic cells 10.

The above description focuses on the controller 312 having control over mass flow into and out of the core 30 of a cryogenic cell 10. However, the controller 312 may also have control over valves (not shown in the figures) that lead to the ports 42, 44 for the set of coils 40 within the pressurizable space 34. In other words, the controller 312 may also have control over the manner in which the fluid to be processed enters the set of coils 40 within the pressurizable space 34. In that case, the controller 312 may respond to an overload or a malfunction by shutting off the flow of fluid to be processed into the set of coils 40.

In managing the work of the cryogenic cells 10, the description above focuses on the use of pneumatic valves. In fact, in a manifold 304 like that shown in FIG. 11, the valves may also be pneumatic. This focus on pneumatic valves is for several reasons. First, in a system that uses cryogenic cells 10, gas to drive pneumatic valves is likely to be readily available. For example, the pneumatic valves may be driven by nitrogen gas. Second, in many embodiments and installations, although certainly not all, cryogenic cells 10 will be used to process flammable gas feedstocks, e.g., those including methane and longer-chain hydrocarbons. In those circumstances, it is helpful to avoid exposing those feedstocks to anything that could cause a spark, and thus, cause a fire. Electrically-operated valves, like those operated by relays and solenoids, have the potential to spark and arc; pneumatic valves do not.

As those of skill in the art will understand, while it may be helpful to eschew anything that could spark or arc in systems according to this description, this is not an absolute rule. For example, if one is processing air to remove moisture, as is suggested by international publication WO2023/004433, sparks may be less of a concern and solenoid- or relay-actuated valves may be used. This is generally true if the gas or fluid being processed is not flammable.

In the description above, all of the cryogenic cells are assumed to be of the same type. However, with no cold head, it is much easier to change the size and proportions of cryogenic cells. As one example, given the dimensions set forth above, a cryogenic cell 10 may have an interior volume of about 400 L, of which the core 30 has a volume of about 200 L. In other words, in the cryogenic cell 10 described above, about 50% of the interior volume of the cryogenic cell 10 is consumed by the core 30.

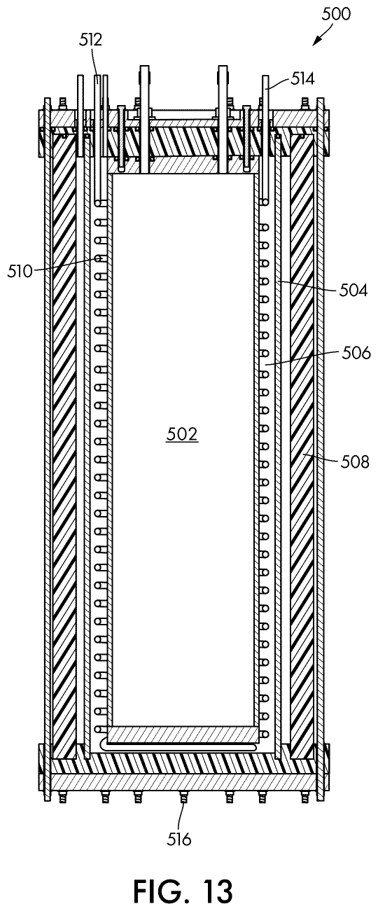

FIG. 13 is a cross-sectional view of a cryogenic cell, generally indicated at 500, according to another embodiment. The cryogenic cell 500 has generally the same components as the cryogenic cell 10 described above; therefore, parts not described here may be assumed to be the same, or about the same, as those described above. As with the cryogenic cell 10, the cryogenic cell 500 has an inner core 502 a mid-wall 504 that defines a pressurizable space 506 between the core 502 and the mid-wall 504, and an outer sidewall 508. A set of coils 510 is positioned in the pressurizable space 506, essentially coiled around, but at a distance from, the core 502. The set of coils 510 has exterior inlet and outlet ports 512, 514.

The cryogenic cell 500 is taller than the cryogenic cell 10, but as can be seen in FIG. 13, the differences between the two cryogenic cells 10, 500 are more distinct along the interior. In particular, while the core 502 extends for most of the height of the cryogenic cell 500, terminating with just enough space between the core 502 and the bottom 516 for a coil of the set of coils 510 to extend beneath it, the core 502 has a significantly smaller radius than the core 30 described above and shown in other figures. This leaves a larger pressurizable space 506 and more space between the set of coils 510 and the core 502. The core 502 may consume, e.g., 25% of the internal volume of the cryogenic cell 500.

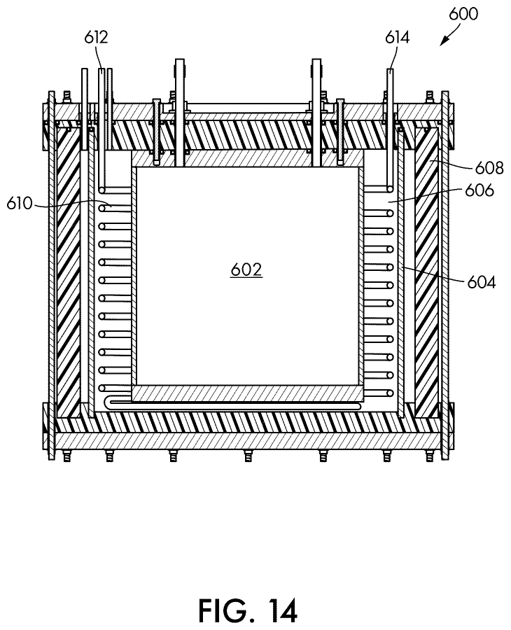

FIG. 14 is a cross-sectional view of a cryogenic cell 600. The cryogenic cell 600 has generally the same components as the cryogenic cell 10 described above; therefore, parts not described here may be assumed to be the same, or about the same, as those described above. As with the cryogenic cell 10, the cryogenic cell 600 has an inner core 602 a mid-wall 604 that defines a pressurizable space 606 between the core 602 and the mid-wall 604, and an outer sidewall 608. A set of coils 610 is positioned in the pressurizable space 606, essentially coiled around, but at a distance from, the core 602. The set of coils 610 has exterior inlet and outlet ports 612, 614.

In general, the cryogenic cell 600 is shorter than the cryogenic cells 10, 500 described above, with a core 602 that consumes somewhat less volume than the core 30 described above, e.g., about 35-40% of the interior volume of the cryogenic cell 600. With no cold head, it becomes much easier to scale the components of cryogenic cells 10, 500, 600. For example, small cryogenic cells with interior volumes of, e.g., 2 L may be constructed. Small-volume cryogenic cells may be particularly useful for small thermal loads, or to provide extensive redundancy in processing larger loads using many cryogenic cells together in parallel.

### Air Cooling Systems

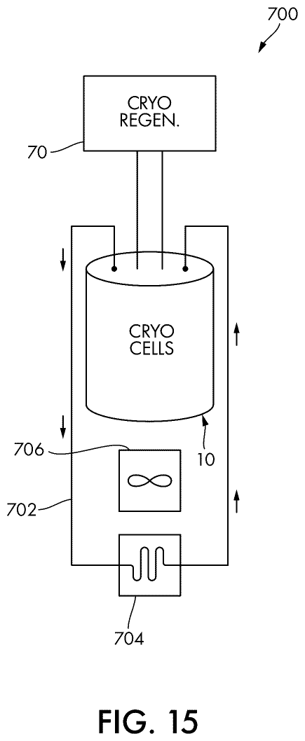

One possible application for cryogenic cells 10, 500, 600 is in an air-cooling system. FIG. 15 is a schematic diagram of a system, generally indicated at 700, that provides air cooling (i.e., air conditioning). In system 700, a circulating coolant runs in a closed loop 702 between a cryogenic cell 10 and a heat exchanger 704. The circulating coolant is typically a liquid and is preferably a liquid with a freezing point lower than that of water. Propylene glycol is one advantageous circulating coolant because of its low freezing point (−59° C. (−74° F.)) and relatively low toxicity.

Air is driven through the heat exchanger 704 by a fan 706 and is cooled by the cold circulating coolant. This cold air can cool a space. Once the circulating coolant absorbs heat from the air, it is returned to the set of coils 40 within the cryogenic cell 10 for recooling and recirculating. As the cryogen within the core 30 of the cryogenic cell 10 absorbs heat from the circulating coolant, it vaporizes and is ultimately compressed back into liquid form by a cryogenic regenerator 70. A pump or pumps may be disposed in the closed loop 702 to move the coolant, although for the sake of simplicity in illustration, pumps are not shown in FIG. 15.

System 700 may be retrofit to use at least some of the existing structure of a conventional air conditioning system. For example, the heat exchanger 704 may be a conventional evaporator in which the liquid coolant of system 700 flows instead of conventional refrigerant. Once cooled, the air may flow through existing ductwork, and the fan 706 may, e.g., be a fan of an existing air conditioning system.

Compared with a traditional air conditioning system, the circulating coolant does not change phase as it circulates through the coolant loop 702. Compared with the cryogenic cooling system described in U.S. Pat. No. 11,306,957, the structure of the cryogenic cell 10 allows for several advantages. For example, in the '957 patent, the coils are connected to the inner vessel that forms the core, and liquid nitrogen is used. Here, by setting the pressure within the pressurizable space 34, heat transfer between the core 30 and the circulating coolant can be controlled to a much greater extent. The use of a cryogenic cell 10 without a cold head may also lead to better thermal performance, i.e., the ability to deal with greater thermal loads per unit time.

Additionally, the cryogen within the core 30 can be chosen so as to minimize thermal overshoot, i.e., overcooling of the circulating coolant. For example, in a traditional air-cooling application, instead of liquid nitrogen, liquid carbon dioxide, which is considerably warmer, may be used. As was disclosed briefly above, the pressure in the core 30 may be sufficient to keep the cryogen in liquid phase.

The use of a cryogenic cell 10 allows control over three main variables that affect the temperature of the coolant in a system like system 700: (1) the selection of the cryogen in the core 30; (2) the pressure within the pressurizable space 34, which influences the rate of heat transfer between the core 30 and the set of coils 40; and (3) the rate at which the coolant flows through the set of coils 40. Typically, the first two of those three things are set when a system like system 700 is initially set up. During operation, while it may be possible to vary the pressure within the pressurizable space 34 (e.g., by adding or releasing pressure using the port 46), the rate at which coolant flows through the set of coils 40 is typically most easily adjustable, by speeding or slowing a pump or pumps in the loop 702.

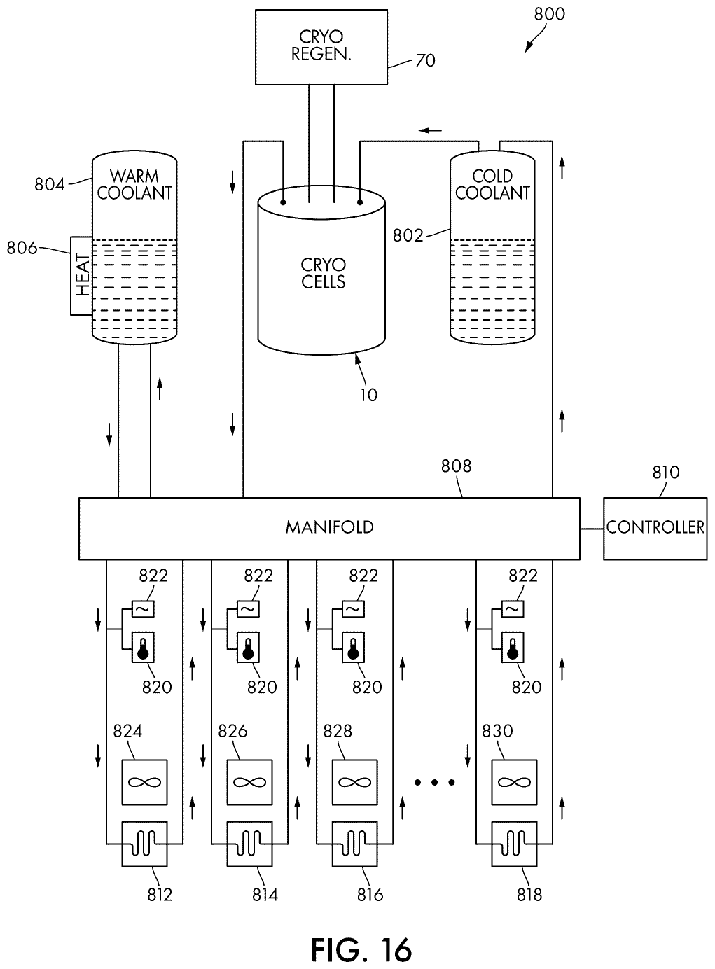

While control over the three variables described above may be sufficient to produce coolant at an appropriate temperature for air cooling, there are situations that may require finer control. FIG. 16 is a schematic illustration of a system, generally indicated at 800, for air conditioning. System 800 also uses one or more cryogenic cells 10, to cool a circulating coolant. As in the description above, the cryogenic cell or cells 10 are connected to a cryogenic regenerator 70. In practical embodiments, there may be any number of cryogenic cells 10 and any number of cryogenic regenerators 70, and those components 10, 70 may be connected via a manifold 304.

In system 800, “cold” coolant that flows through the set of coils 40 in the cryogenic cells 10 is mixed with “warm” coolant that is held and heated in a separate reservoir. This mixing allows system 800 to produce circulating coolant at the desired temperature or temperatures.

More particularly, a first reservoir 802 is connected to the cryogenic cells 10. When coolant is released from the first reservoir 802, it flows into the set of coils 40 within the cryogenic cell 10 for cooling. A separate, second reservoir 804 holds the same coolant fluid and is associated with a heater 806. The heater 806 may be of any suitable type, including a resistance heater, a Pelletier effect thermoelectric heater, a gas or oil burner, etc. While the heater 806 is shown schematically on the outside of the second reservoir 806, the heater may be within the second reservoir 804.

In the illustrated embodiment, cold coolant from the first reservoir 802 and warm coolant from the second reservoir 804 flow to a manifold 808. Under the control of a controller 810, the manifold 808 mixes warm and cold coolant to the appropriate temperature or temperatures. (While a manifold 808 is shown in FIG. 16, individual valves or other mixing apparatus may be used in other embodiments.) The controller 810, like other controllers 312 disclosed here, may be a microcontroller, an application-specific integrated circuit (ASIC), an integrated, embedded system including one of those components, a programmable logic controller (PLC), or any other computing device capable of performing the functions described here.

In system 800, there are a plurality of individual heat exchangers 812, 814, 816, 818, each of which is coupled to the manifold 808 to receive cold coolant. The temperature and flow rate of the coolant supplied to each heat exchanger 812, 814, 816, 818 by a temperature sensor 820 and a flow sensor 822. The manifold 808 may be configured such that the temperature of the coolant received by each heat exchanger 812, 814, 816, 818 is different, such that the each heat exchanger 812, 814, 816, 818 can more easily provide precise cooling to the space it is intended to cool.

Each heat exchanger 812, 814, 816, 818 is coupled to a fan 824, 826, 828, 830 to move air through the heat exchanger 812, 814, 816, 818 for cooling. The fans 824, 826, 828, 830 may or may not be of the same sizes. For example, if a larger space is to be cooled, the fan 824 assigned to that space may be larger, and the heat exchanger 812 may, in at least some cases, receive colder coolant so that it can generate a larger temperature differential.

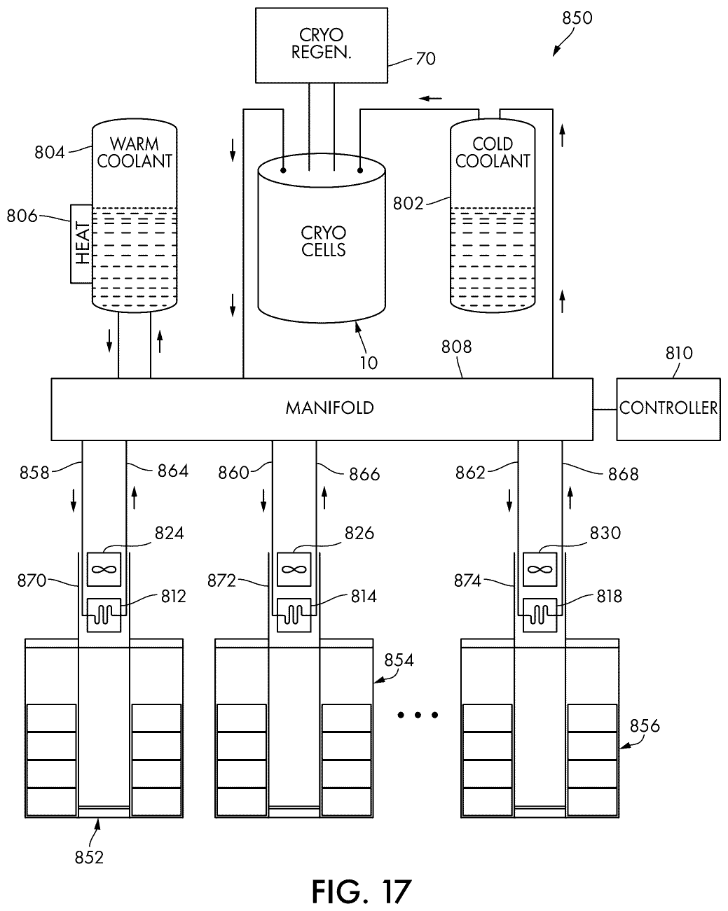

FIG. 17 is a schematic illustration of an application of system, generally indicated at 850, that is an application of system 800 of FIG. 16. In system 850, a number of individual structures 852, 854, 856 are cooled. More specifically, as shown in FIG. 17, each structure 852, 854, 856 has a heat exchanger 812, 814, 818 and an associated fan 824, 826, 830. As in system 800, a manifold 808 supplies a circulating coolant to the individual heat exchangers 812, 814, 818 through coolant supply lines 858, 860, 862 and receives warm coolant from the heat exchangers 812, 814, 818 through coolant return lines 864, 866, 868.

Most centralized air conditioning systems use a large central fan, a large central heat exchanger, and have ductwork arrayed throughout the structure to carry cooled air to specific rooms, zones, or areas. The ductwork consumes considerable space and can lead to considerable heat or cooling loss if not properly insulated. The natural inclination may be to reduce the size of the ductwork, but if the ductwork is too small, it may not be possible to move enough cool air into a room, zone, or area to cool it adequately.

By contrast, systems like systems 800 and 850 may require very little ductwork. In systems 800 and 850, it is the coolant that circulates from the manifold to the individual structures 852, 854, 856 or spaces. The coolant circulation can be accomplished using, e.g., conventional copper plumbing or piping, schedule 40 PVC pipe, or other conventional types of liquid conduit used in building construction, all of which is much smaller than a typical air duct. While at least the coolant supply lines 858, 860, 862 would typically be insulated, even insulated, the space required is still much smaller than that required for ductwork. Moreover, while there would typically be pumps coupled to the coolant supply and return lines 858, 860, 862, 864, 866, 868 (not shown in FIG. 17), the coolant does not change phase while in use and, in case of a leak or breach, may be less toxic than, e.g., traditional haloalkane refrigerants. In general, a system 800, 850 according to an embodiment of the invention may have more coolant supply and return lines 858, 860, 862, 864, 866, 868 than it does ductwork.

The heat exchangers 812, 814, 818 and their associated fans 824, 826, 830 sit in a plenum space, short duct, or other kind of small enclosure 870, 872, 874, often directly coupled to an individual register that delivers cool air. These components are sized specifically for the individual structures 852, 854, 856 or spaces and their thermal needs. Note that, the above description notwithstanding, in some cases, small amounts of ductwork may be used within a smaller space, e.g., to connect multiple registers that serve the same room or space. However, if, e.g., different parts of the same space have different thermal conditions or needs relative to one another, multiple heat exchangers and fans may be used instead of a single heat exchanger, a single fan, and ductwork.

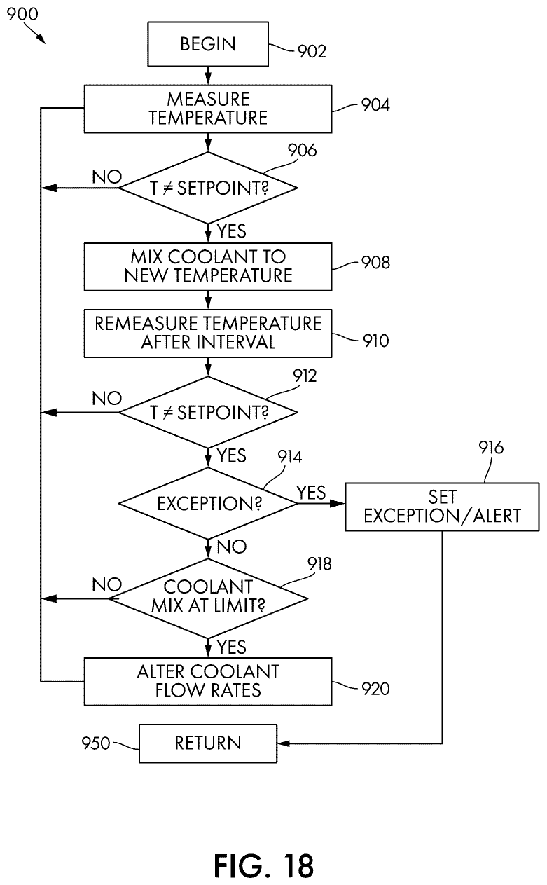

System 850 may be particularly useful in cooling computing equipment. As so-called “cloud” computing becomes a part of daily life for many companies and individuals, different solutions for supporting the necessary computing equipment have arisen. For example, system 850 may be installed in a traditional large data center, with its various heat exchangers 812, 814, 818 and fans 824, 826, 830 distributed around the building, perhaps with some small sections of ductwork. As will be described below with respect to FIG. 18, such an installation could potentially provide an adaptable solution to address the varying loads and cooling needs of equipment around the data center. Moreover, as will also be described below with respect to FIG. 18, increased cooling can often be achieved without increasing fan speed, or at least, with limited increases in fan speed. That may help to reduce the overall noise level within the data center.

However, the structures 852, 854, 856 illustrate another possibility: individual cooling within modular, relatively portable computing equipment support structures. In recent years, modular, easily assembled small computing equipment support structures or “pods” have been developed that control the environment around, and support the needs of, several racks of computing equipment. For example, one of these structures may provide space for up to twelve racks of computing equipment in two rows of 6 with a central “cold” aisle between them. Such a structure may also provide raceways for cabling, a power supply, and power distribution units, and may even provide some cooling. In one embodiment, the structures 852, 854, 856 could be modular computing equipment support structures. If used to support such structures 852, 854, 856, a system like system 850 could provide highly individualized cooling for each structure 852, 854, 856, varying the cooling rapidly as the load on the computing equipment, and thus, the thermal load, increases.

FIG. 18 is a schematic flow diagram of a method, generally indicated at 900, for controlling a system like systems 800, and 850 of FIGS. 16 and 17. (For simplicity, the remainder of this description will refer to system 800, although the description is equally applicable to system 850 of FIG. 17.) Method 900 begins at 902 and continues with task 904. In task 904, the temperatures of the individual areas served by system 800 are taken. Method 900 continues with task 906, a decision task.

In a traditional air conditioning system, when a space is warmer than the setpoint temperature, the response is generally limited to turning the system on, or in some cases, increasing the fan speed. As may be apparent from the above description, in system 800 and its variations, the response may be more varied. While simply turning system 800 on and/or increasing fan speed are possible responses to a finding that an area is too warm, in order to illustrate the range of responses possible with system 800, method 900 assumes something else: the primary or first response to a finding that an area is not at its desired temperature setpoint should be for the controller 810 to direct the manifold 808 to mix the coolant for that zone to a different temperature.

More specifically, if the measured temperature is not at the desired setpoint (task 906: NO), method 900 continues with task 908 and coolant is mixed to a new temperature. Note that while much of this description is concerned with cooling, it is possible for system 800 to provide at least some heating to a space, if desired, by omitting cold coolant from the first reservoir 802 and relying only on the warm coolant in the second reservoir 804. The maximum temperature to which a space might be heated depends on the temperature at which the heater 806 maintains the coolant in the second reservoir.

Task 906 generalizes: if the measured temperature is not at the desired setpoint (task 906: NO), the measured temperature may be either above or below the desired setpoint. The controller 810 would typically establish whether the measured temperature is above or below the desired setpoint before taking action in task 908. If the measured temperature is too hot, the response would be for the manifold 808 to mix colder coolant for that zone or area; if the measured temperature is too cold, the response would be for the manifold 808 to mix warmer coolant or to omit cold coolant altogether for that zone or area.

Method 900 continues with task 910. In task 910, after some defined interval of time, the temperature is measured again. Method 900 continues with task 912, another decision task. In task 912, if the temperature is still not at the desired setpoint (task 912: YES), method 900 continues with task 914, another decision task. If the temperature is at the desired setpoint (task 912: NO), control of method 900 returns to task 904.

As method 900 iterates through multiple adjustments to the coolant mix, the controller 810 tracks the number of adjustments that have been made, their effect, and whether a malfunction has occurred. Generally speaking, if numerous adjustments to the coolant mix have failed to achieve the desired setpoint, or if some malfunction is detected, that is an indication that an exception is present. If an exception is present (task 914: YES), an exception is set or thrown and an alert is established in task 916 before method 900 returns at 950.

If the controller 810 determines that there is no exception, that system 800 is operating normally, and that more adjustments are necessary (task 914: NO), method 900 continues with task 918, yet another decision task. In system 800, coolant mixing allows for a wide variety of setpoint temperatures. However, as with all things, there is a limit: if manifold 808 is currently delivering only cold coolant from the first reservoir 802 or only warm coolant from the second reservoir 804 and the zone or space still needs to be colder or warmer, respectively, the limit has been reached. Task 918 determines whether the coolant mixing limit has been reached. If the coolant mixing limit has not been reached (task 918: NO), method 900 returns to task 904.

If the coolant mixing limit has been reached (task 918: YES), there are still things that a system like system 800 can do to try to achieve the desired setpoint temperature. During operation, the easiest of these things is to change the various flow rates, as indicated in task 920. There are two main flow rates that may be altered in task 920: the flow rate of coolant into and within the cryogenic cells 10, and the flow rate of coolant from the manifold 808 to the individual heat exchanger or exchangers 812, 814, 816, 818.

For example, slowing the flow of coolant into the cryogenic cells 10 increases the dwell time within the cryogenic cells 10 and generally results in more heat transfer and colder coolant. However, as those of skill in the art will realize, there is a limit to how cold the coolant can be. For that reason, the controller 810 would typically be programmed with a maximum differential between the temperature of the coolant and the desired air temperature in the zone or space, and the first operation in task 920 would be to ensure that the coolant meets that maximum differential. If the maximum differential temperature has been reached, it is likely that the issue is not the coolant temperature. Rather, the issue could be that the thermal load in the particular zone or space is so great that coolant is not being supplied to the heat exchanger 812, 814, 816, 818 quickly enough. In that case, the controller 810 may direct the manifold to increase the rate at which cold coolant is supplied to the heat exchanger 812, 814, 816, 818.

FIG. 18 assumes that method 900 continues to run in continuous loop absent some exception. Thus, when task 920 is complete, method 900 returns to task 904. If, in a method like method 900, exceptions are frequently thrown, the controller 810 may be adapted to analyze the nature or pattern of exceptions and to make specific recommendations, such as a recommendation that the cryogen within the core 30 be replaced with a different cryogen, or that the pressure in the pressurizable space 34 be altered to change the rate of heat transfer.

As was noted above, in some embodiments of control methods like method 900, the method may alter the speed of the fan 824, 826, 828, 830. However, one advantage of method 900 is to increase cooling at a constant fan speed.

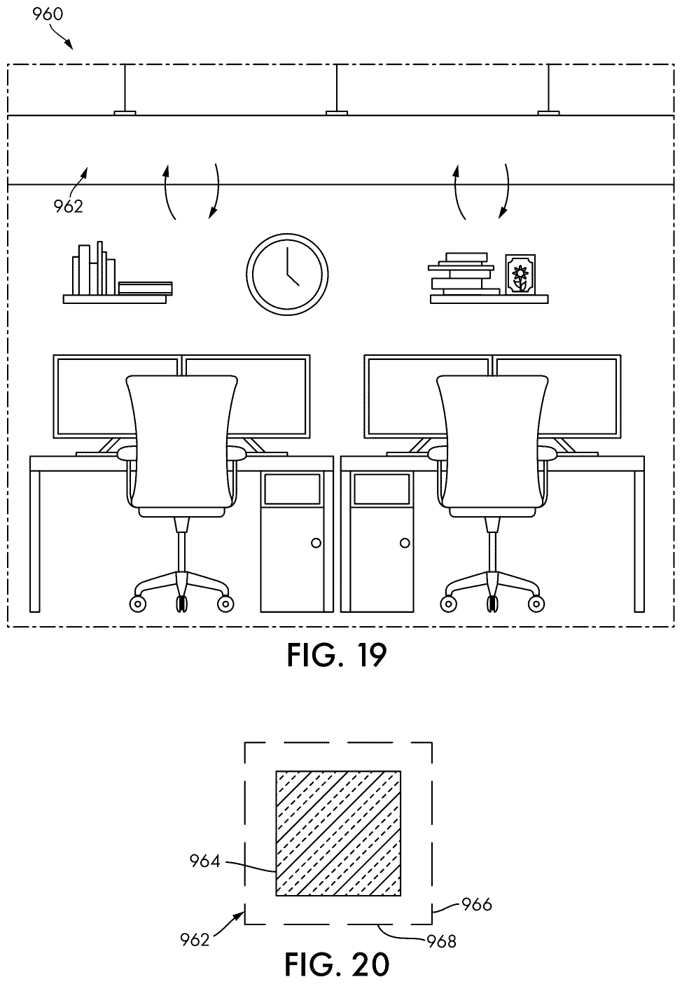

The previous description has shown a heat exchanger 704, 812, 814, 816, 818 coupled to a fan 706, 824, 826, 828, 830. That need not always be the case. In some situations, a heat exchanger 704, 812, 814, 816, 818 may be provided separately, relying on existing airflow in the space to achieve cooling. FIG. 19 is a perspective view of an office space, generally indicated at 960. In the office space 960, a chilled beam 962 is suspended from the ceiling of the space. FIG. 20 is a cross-sectional view of the chilled beam 962.

With the chilled beam 962, as shown in FIG. 19, air currents within the space 960 rise to the chilled beam 962. The chilled beam 962 itself is a passive device: it contains a heat exchanger 964 within an enclosure that has openings 968. The openings 968 may be simple openings, they may be louvered, etc. As hot air naturally rises within the space 960, it encounters the chilled beam 962, is cooled, and sinks toward the floor level. The chilled beam 962 is connected to one or more cryogenic cells 10 to maintain its temperature. The chilled beam 962 is passive, but in other embodiments, it could be active, i.e., coupled to a fan 706, 824, 826, 828, 830.

As those of skill in the art will understand, while the use of cryogenic cells in these systems and methods is advantageous, and a particular form of cryogenic cell 10 is described above, the nature of the cryogenic cell is not critical. The cryogenic cells used in systems 700, 800, 900 described here could be, e.g., those described above, those described in U.S. Pat. No. 11,306,957, those described in U.S. Pat. No. 11,448,459, etc. U.S. Pat. Nos. 11,306,957 and 11,448,459 are incorporated by reference in their entireties.

Moreover, in the description above, other components may be necessary or helpful in returning the cryogen to the core 30 in liquid form. Thus, the term “cryogenic regenerator” should be read broadly to include all of the components necessary to compress, condense, or otherwise regenerate the vaporized cryogen into liquid form.

This description uses the term “about.” When that term is used to modify a numerical value or range, it means that that numerical value or range can vary so long as the described end result does not. If it cannot be determined what range would not cause the described end result to vary, the term should be interpreted as meaning ±10%.

While the invention has been described with respect to certain embodiments, the description is intended to be exemplary, rather than limiting. Modifications and changes may be made within the scope of the invention, which is defined by the appended claims.

What is claimed is:

1. A cooling system, comprising:
a plurality of air-coolant heat exchangers;
at least one cryogenic cell; and
a cooling circuit connected between each of the plurality of air-coolant heat exchangers and the at least one cryogenic cell, the cooling circuit conveying a circulating coolant between the plurality of air-coolant heat exchangers and the at least one cryogenic cell without a change in phase of the circulating coolant.

2. The cooling system of claim 1, further comprising a coolant mixing subsystem, comprising:
a first coolant reservoir connected to the at least one cryogenic cell and adapted to hold and to direct a first coolant through the at least one cryogenic cell to cool the first coolant to a first temperature;
a second coolant reservoir associated with one or more heaters and adapted to hold and to heat a second coolant to a second temperature, the second temperature being higher than the first temperature, and the first coolant and the second coolant being the same except as to temperature;
a mixing apparatus constructed and arranged to mix the first coolant and the second coolant to create the circulating coolant.

3. The cooling system of claim 1, further comprising a fan associated with each of the plurality of air-coolant heat exchangers.

4. The cooling system of claim 3, further comprising a coolant mixing subsystem, comprising:
a first coolant reservoir connected to the at least one cryogenic cell and adapted to hold and to direct a first coolant through the at least one cryogenic cell to cool the first coolant to a first temperature;
a second coolant reservoir associated with one or more heaters and adapted to hold and to heat a second coolant to a second temperature, the second temperature being higher than the first temperature, and the first coolant and the second coolant being the same except as to temperature;
a mixing apparatus constructed and arranged to mix the first coolant and the second coolant to create the circulating coolant.

5. The cooling system of claim 4, wherein the mixing apparatus comprises a mixing valve.

6. The cooling system of claim 4, wherein the mixing apparatus comprises a manifold.

7. The cooling system of claim 6, wherein the manifold distributes the circulating coolant to each of the plurality of air-coolant heat exchangers and receives spent coolant from each of the plurality of air-coolant heat exchangers for recirculation to the first coolant reservoir and the second coolant reservoir.

8. The cooling system of claim 7, wherein the manifold mixes the circulating coolant to a different temperature for each of the plurality of air-coolant heat exchangers.

9. The cooling system of claim 3, wherein the at least one cryogenic cell comprises:
a core adapted to contain a cryogen, the core having one or more ports to an outside of the at least one cryogenic cell that allow the cryogen to circulate into and out of the core;
a mid-wall disposed around the core and spaced from the core, the mid-wall defining, in part, a space in selective, partial thermal communication with the core, the space being at least substantially airtight and adapted to be filled or evacuated with a compressible fluid that (1) increases or decreases thermal communication with the core in accordance with a pressure of the compressible fluid within the space, and (2) places contents of the space under the pressure of the compressible fluid; and
a conduit positioned within the space such that the conduit does not make physical contact with the core, the conduit being connected with inlet and outlet ports in the cryogenic cell.

10. The cooling system of claim 1, wherein at least one of the plurality of air-coolant heat exchangers is installed in a chilled beam configuration.

11. A cooling system, comprising:
at least one cryogenic cell;
a first coolant reservoir connected to the at least one cryogenic cell and adapted to hold and to direct a first coolant through the at least one cryogenic cell to cool the first coolant to a first temperature;
a second coolant reservoir associated with one or more heaters and adapted to hold and to heat a second coolant to a second temperature, the second temperature being higher than the first temperature, and the first coolant and the second coolant being the same except as to temperature;
a manifold constructed and arranged to mix the first coolant and the second coolant to create a circulating coolant;
a plurality of heat exchangers, each of the plurality of heat exchangers placed in a location spaced from others, and each of the plurality of heat exchangers receiving the circulating coolant from the manifold and returning spent circulating coolant to the manifold; and
a fan associated with each of the plurality of heat exchangers.

12. The cooling system of claim 11, wherein each of the plurality of heat exchangers is placed in a different enclosed space.

13. The cooling system of claim 12, wherein each of the plurality of heat exchangers receives the circulating coolant from the manifold at a different temperature.

14. The cooling system of claim 13, wherein each of the plurality of heat exchangers is located in a separate room or is associated with a separate structure.

15. The cooling system of claim 11, wherein at least one of the plurality of heat exchangers is installed in a chilled beam configuration.

16. A method of controlling a cooling system, comprising:
providing a liquid coolant at a first temperature using a cryogenic cell;
passing the liquid coolant through an air-coolant heat exchanger to generate cold air;
measuring the temperature of a space cooled by the cold air from the air-coolant heat exchanger; and
adjusting the first temperature of the liquid coolant in accordance with the measured temperature of the space.

17. The method of claim 16, wherein said providing further comprises:
mixing a supply of warm liquid coolant with a supply of cold liquid coolant from the cryogenic cell to generate the liquid coolant at the first temperature.

18. The method of claim 17, wherein said adjusting further comprises:
mixing the supply of warm liquid coolant with the supply of cold liquid coolant to generate the liquid coolant at a temperature different from the first temperature.
